(19) United States
(12) Patent Application Publication
(10) Pub. No.: US 2015/0262854 A1
(43) Pub. Date: Sep. 17, 2015

(54) WAFER ETCHING SYSTEM AND WAFER ETCHING PROCESS USING THE SAME

(71) Applicant: ROREZ SYSTEMS CORPORATION, Yongin-si, Gyeonggi-do (KR)

(72) Inventors: Ki-Yong You, Seoul (KR); Saeng-Man Park, Suwon-si (KR); Masahiko Uchiyama, Yongin-si (KR)

(21) Appl. No.: 14/376,718

(22) PCT Filed: Jul. 9, 2013
(86) PCT No.: PCT/KR2013/006076

§ 371 Date: Aug. 5, 2014

(30) Foreign Application Priority Data
Nov. 30, 2012 (KR) 10-2012-0138084

(51) Int. Cl. H01L 21/677; H01L 21/67; H01L 21/683; H01J 37/32

(52) U.S. Cl. CPC H01L 21/67742; H01J 37/32899; H01J 37/32889; H01J 37/32816; H01J 37/32724; H01J 37/32697; H01J 37/32733; H01L 21/67069; H01L 21/67075; H01L 21/6833; H01L 21/67155

(57) ABSTRACT

Disclosed are a wafer etching system and a wafer etching process using same that enable thin wafers to be smoothly manufactured and transferred. The present invention includes: a wafer grinding device for mechanically etching wafers; an aligner for aligning etched wafers from the wafer grinding unit; a dry etching device for etching the wafers once more that are aligned by the aligner; a wafer transfer device for transferring the wafers between the aligner and the dry etching device; and a tape mounter for performing taping on the wafers that have completed etching from the dry etching device.

### TECHNICAL FIELD

The present invention relates to a wafer etching system, and more particularly to a wafer etching system capable of manufacturing and transferring a thin wafer smoothly by installing a dry etching chamber and a transfer chamber in series between a conventional wafer grinder and a tape mounter attaching to a protection tape for protecting and handling a wafer and attaching a tape for dicing a wafer, and a wafer etching process using the same.

### BACKGROUND ART

The miniaturization and the high functionality of an electronic device should be supported by a manufacturing process of integrated circuit, and a manufacturing process of a thin wafer is essentially required in order for that.

In general, in order to reduce a thickness of a wafer to be 30 μm or thinner than that, a back grinding process grinding backside of the circuit board in a mechanical method is performed first, and a chemical mechanical polishing (CMP) process is performed to reduce the thickness of a wafer.

However, the above method has not only a problem of brokenness, warpage and thermal damage of a wafer due to mechanical contact and frictional heat, but also a surface-remaining stress causing brokenness when a small impact is applied.

Further, as the thickness of a wafer is reduced, problems such as a wafer handling, complexity of process, etc. are induced to cause increase of manufacturing cost.

Therefore, a process according to which mechanical grinding is performed while a protection film is attached to a surface of a wafer with electric circuit to a certain thickness, that is 100 μm to 200 μm and then dry etching is performed to reduce the thickness is under development.

According to a general dry etching process, a plasma source using a main reaction gas of CxFy gases or SxFy gases and a sub gas of N2, Ar, O2, etc. in low pressure of numbers of mTorr to hundreds of mTorr is applied to an upper region, and RF power of tens of KHz to GHz is applied to a lower chuck separately to generate plasma to induce chemical reaction so that a wafer etching process is performed.

However, the above etching process performed by a conventional apparatus is a low pressure process so that etching speed for a thick wafer is low to lower productivity.

Additionally, one of important factors in an etching process for making a wafer very thin is a high temperature generated in the etching process. In the conventional etching process, an electro static chuck (ESC) is used in order to cool down a wafer that is heated in the process. In this etching process, a technology for cooling down a wafer is different in characteristic in each process so that various chuck design is applied per wafer etching apparatus.

Conventionally, the chuck has a circular disc shape with a plurality of grooves or with a plurality of porous holes to apply helium gas through the grooves or the porous holes in order to cool down a heated wafer.

On the other hand, when plasma is generated by applying RF power onto the conventional chuck, there exists a problem that unwanted plasma is generated in a space between a wafer and the minute porous holes or the grooves to damage the wafer frequently.

Additionally, in case of a thin wafer, the conventional method using a lift pin for chucking and dechucking induces a problem of a local damage unlike a thick wafer.

Further, there exsits a problem of warpage or sagging of a wafer to make transferring of the wafer harder when the wafer is transferred.

### DETAILED DESCRIPTION OF THE INVENTION

### Objects of the Invention

Therefore, the object of the invention is to provide a wafer etching system capable of completion of taping process in order to making transferring easy after mechanically grinding a backside of a wafer with integrated circuit with a protection film attached thereto, transferring the wafer to a plasma etching apparatus, and etching the wafer to make the wafer thinner, and a wafer etching process using the wafer etching system.

The other object of the invention is to provide a wafer etching system capable of handling a grinded wafer with thin thickness in order not to damage the grinded wafer when transferring the grinded wafer, and a wafer etching process using the wafer etching system.

### Technical Solution

A wafer etching system according to the present invention may include a wafer grinding device etching the wafer mechanically, an aligner aligning the wafer that is etched by the wafer grinding unit, a dry etching device etching the wafer again, which is aligned by the aligner, a wafer transfer device transferring the wafer between the aligner and the dry etching device, a tape mounter performing taping process to the wafer that is etched by the dry etching devic, so that the wafer etching system is capable of reducing a thickness of a wafer while removing stress remaining in the wafer, which is generated by mechanical etching.

On the other hand, the dry etching device may include a process chamber capable of rapidly maintaining vacuum state, a first gate valve configured to open and to close the process chamber to be connected to the wafer transfer device, a chuck installed in the process chamber to support the wafer transferred by the wafer transfer unit, a plasma unit connected to the process chamber to etch the wafer of large area rapidly, which is supported by the chuck. The chuck may include an electrostatic part configured to apply static electricity, a cooling gas providing part providing cooling gas through a cooling gas hole penetrating the electro static part, a vacuum forming part configured to form a vacuum through the cooling gas hole, an on/off valve configured to be turned on/off to connect the cooling gas providing part and the vacuum forming part to the cooling gas hole, an adjust valve adjusting a degree of vacuum of the vacuum forming part and adjusting an amount of cooling gas of the cooling gas providing part. And the chuck may further include a masking ring for protecting UV tape attached to the wafer when the wafer is dry etched after taping is completed by the tape mounter, and an elevating device raising and lowering the masking ring.

On the other hand, the plasma unit may include a first plasma unit connected with the process chamber to project high pressured first etching gas into the process chamber in order to rapidly etch a wafer with large area, and a second plasma unit connected with the process chamber to project low pressured second etching gas into the process chamber in order to remove stress of the wafer and to make wanted roughness of the wafer.

On the other hand, the wafer transfer device may include a transfer chamber rapidly maintaining vacuum state, a second gate valve opening or closing the transfer chamber, a transferring arm installed in the transfer chamber to transfer the wafer, and an end effector connected to an end portion of the transferring arm, which is capable of attaching the wafer thereto. In this case, the end effector may be an adhesive type end effector having adhesive spreaded thereon in a regular pattern. Also, the end effector may be an electrostatic type end effector capable of applying static electricity. Also, the end effector may be an adhesive/electrostatic end effector capable of applying static electricity and having adhesive spreaded thereon in a regular pattern. The wafer transfer device may further include a wafer-drop prevention device installed in the transfer chamber for preventing the wafer from being dropped from the end effector when forming vacuum.

A wafer etching process through the wafer etching apparatus according to the present invention may include firstly grinding a wafer by a wafer grinding device; transferring the wafer to an aligner; attaching the wafer by an end effector of a wafer transfer device; transferring the wafer attached to the end effector into a transfer chamber; closing a second gate valve to vacuate the transfer chamber; opening a first gate valve when a vacuum state of the transfer chamber becomes equal to a vacuum state of a process chamber to transfer the wafer in the transfer chamber onto a chuck in the process chamber; separating the wafer from the end effector by applying static electricity to the chuck and forming vacuum by a vacuum forming part, closing the first gate valve to highly vacuate the process chamber to etch the wafer; attaching the wafer that is etched to the end effector when etching is completed; opening the first gate value and the second gate valve to transfer the wafer to the aligner; transferring the wafer to a tape mounter to performs taping.

On the other hand, a wafer etching process for etching a wafer on which taping is completed by the tape mounter, may include firstly grinding a wafer by a wafer grinding device; transferring the wafer to an aligner; transferring the wafer to a tape mounter to perform taping; transferring the wafer with a tape to the aligner and attaching the wafer by an end effector of a wafer transfer device; transferring the wafer attached to the end effector into a transfer chamber; closing a second gate valve to vacuate the transfer chamber; opening a first gate valve when a vacuum state of the transfer chamber becomes equal to a vacuum state of a process chamber to transfer the wafer in the transfer chamber onto a chuck in the process chamber; separating the wafer from the end effector by applying static electricity to the chuck and forming vacuum by a vacuum forming part; lowering a masking ring for protect a taping portion on the wafer; closing the first gate valve to highly vacuate the process chamber to etch the wafer; raising the masking ring when the etching is finished; attaching the wafer that is etched to the end effector; opening the first gate value and the second gate valve to transfer the wafer to the aligner.

### Advantageous Effects

According to the wafer etching system and the wafer etching process, the wafer is transferred to the transfer chamber by an in-line automation system after wafer grinding, transferred to the process chamber to be dry etched and then transferred again to the transfer chamber to be conveyed to the wafer mounter, so that productivity is enhanced.

Further, the surface remaining stress generated in the grinding process is removed during dry etching by using plasma to enhance surface strength and to prevent wafer crack in advance.

According the adhesive chuck used for wafer transferring, all surface of the wafer is attached to the adhesive chuck to be transferred so that the wafer warpage and the wafer sagging, that are generated when the wafer is transferred by a conventional method in which a lower surface of the wafer is lifted and transferred, are prevented.

Further, according to the electrostatic chuck, the mischucking due to surface pollution when transferring to chamber is minimized, and wafer circuit damage is minimized since lower voltage is applied thereto.

Further, the wafer etching process etching the wafer with the frame prevents the wafer warpage and sagging of the wafer while transferring, and reduces wafer distortion while etching through a tension of the tape attached between the frame and the wafer so that reduction of electrostatic force induced by the wafer distortion when loading the wafer onto the chuck is detected in advance.

### BRIEF DESCRIPTION OF THE DRAWINGS

FIG. 1 is a schematic view showing a total structure of a wafer etching system according to an embodiment of the present invention.

FIG. 2 is a figure showing an adhesion type end effector of a wafer etching system according to an embodiment of the present invention.

FIG. 3 is a figure showing an electrostatic end effector of a wafer etching system according to an embodiment of the present invention.

FIG. 4 is a figure showing a hybrid end effector of the adhesion type end effector and the electrostatic end effector, the hybrid end effector of a wafer etching system according to an embodiment of the present invention.

FIG. 5 is a figure showing a structure of a chuck of a wafer etching system according to an embodiment of the present invention.

FIG. 6 is a figure showing a structure of a chuck with a masking ring of a wafer etching system according to an embodiment of the present invention.

FIG. 7 is a figure showing a transferring process of a wafer transfer device in a wafer etching system according to an embodiment of the present invention.

### EMBODIMENTS OF THE INVENTION

The invention may be embodied in many different forms, and the invention is described more fully hereinafter with reference to the accompanying drawings, in which exemplary embodiments of the invention are shown. However, this invention should not be construed as limited to the embodiments set forth herein, but this invention should be understood to include all modifications, equivalents or substitutions within the idea and technics of the present invention.

Numerical terms such as “first”, “second”, etc. may be used as ordinal numbers to indicate various structural elements, however, the structural elements should not be limited by the terms. The terms are only used to distinguish one structural element from another structural element. For example, a first structural element may be named as second structural element if the right is not beyond the scope, the same applies to the second structural element that may be named as the first structural element.

The terms used in the present application are only to explain the specific embodiment and is not intended to limit the present invention. The terms “a”, “an” and “the” mean “one or more” unless expressly specified otherwise. The terms “including”, “comprising”, etc., are to designate features, numbers, processes, structural elements, parts, and combined component of the application, and should be understood that it does not exclude one or more different features, numbers, processes, structural elements, parts, combined component.

All terms described hereinafter, which include technical or scientific terms, have same meaning understood by a person ordinary skilled in the art, if not differently defined.

Terms which are defined in a conventional dictionary should be construed to have the same meaning as the meaning contextually understood in relating technical field, and should not be construed ideally or excessively formally, if not clearly defined.

Hereinafter, the embodiments of the present invention will be explained.

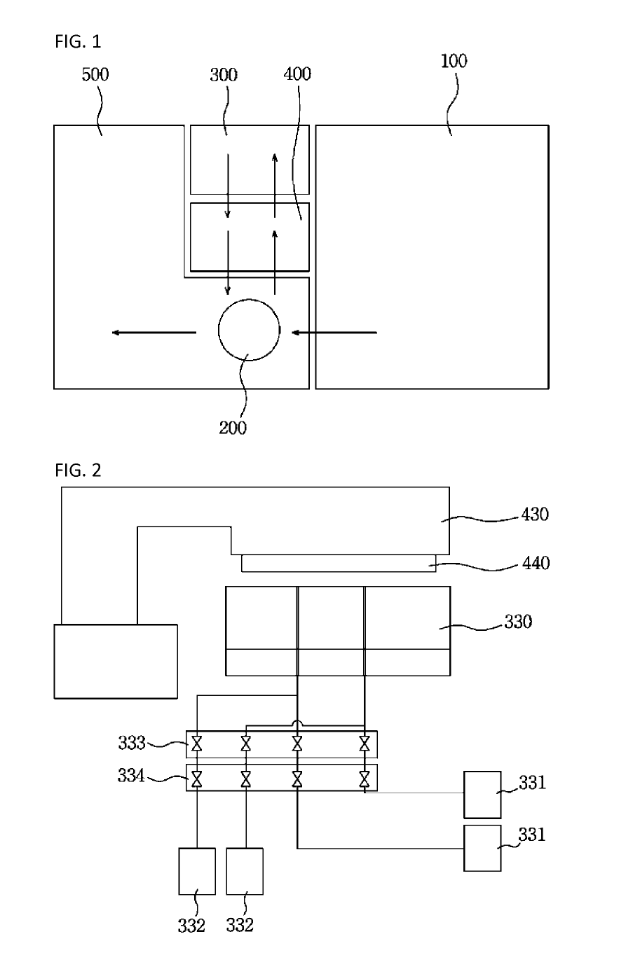

FIG. 1 is a schematic view showing a total structure of a wafer etching system according to an embodiment of the present invention.

Referring to FIG. 1, a wafer etching system according to an embodiment of the present invention includes a wafer grinding device 100, an aligner 200, a dry etching device 300, a wafer transfer device 400 and a tape mounter 500.

The grinding device 100 grinds a backside of a wafer to have a thickness of tens of μm to hundreds of μm through a back grinding process in which the wafer with 750 μm is grinded. That is the thickness for minimizing a problem of crack, warpage, etc. of a wafer, which are generated by physical force applied to the wafer in the mechanical grinding process, and for preventing damage of the wafer.

The aligner 200 aligns wafers etched by the grinding device. In a conventional method, the wafers are transferred to the tape mounter 500 through the aligner.

The dry etching device 300 etches the wafer that is firstly grinded to make the wafer to be thinner. The dry etching device 300 may include a process chamber 310, a first gate valve 320, a chuck 330, and a plasma unit 340. The process chamber 310 is connected with a dry pump and a turbo pump for rapidly arriving at vacuum and maintaining the vacuum when etching the wafer. For the process chamber 310, rapidly maintaining vacuum is possible. The first gate valve 320 is open when a wafer is transferred into the process chamber, and closed when the wafer is etched to maintain the vacuum of the process chamber 300.

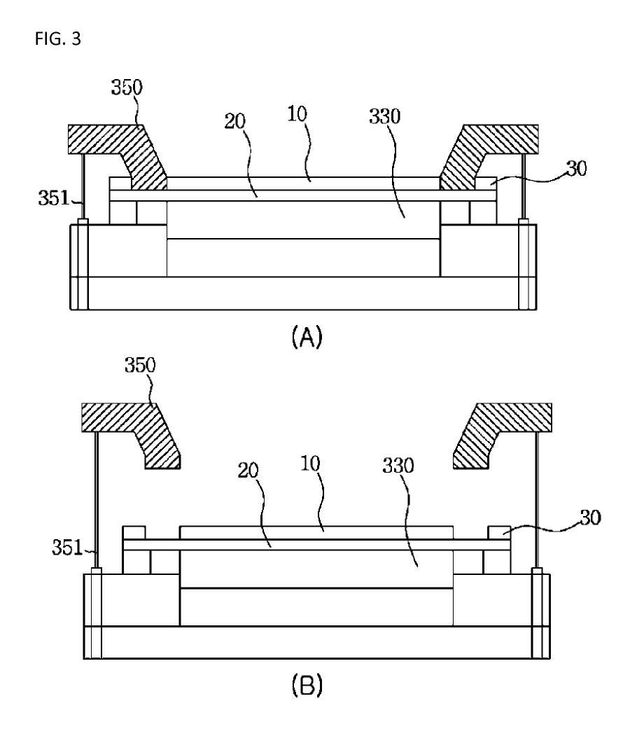

FIG. 2 is a figure showing a structure of a chuck of a wafer etching system according to an embodiment of the present invention. FIG. 3 is a figure showing a structure of a chuck with a masking ring of a wafer etching system according to an embodiment of the present invention.

Referring to figures, the chuck 330 is installed inside of the process chamber 310 to separate and to support a transferred wafer. Then, the chuck 330 may fasten the wafer during dry etching process. For fastening the wafer, an electro static chuck including electro static part capable of generating static electricity may be used. Additionally, the chuck supports a wafer and fastens the wafer horizontally, and the chuck may include a cooling gas providing part 331 for cooling the wafer through cooling gas when etching is finished, and a vacuum forming part 332 for easily separating a wafer from an end effector. The vacuum forming part 332 may separates the wafer from the end effector by pressure sucking air for vacuum when the wafer attached to the end effector is on the chuck.

On the other hand, when a wafer with a frame attached thereto is used as shown in FIG. 3, the frame and a tape portion are protected by using a masking ring 350 of ceramic based material for preventing arc in etching process and for preventing burning the tape. The masking ring 350 is elevated by a masking ring elevating device 350 and in an up-state before the wafer with the frame is on the chuck, and the masking ring 350 is lowered when the wafer with the frame is on the chuck to protect the frame and the tape portion.

The plasma unit 340 rapidly etches the wafer on the chuck by using plasma. The plasma unit 340 may include a first plasma unit 341 connected with the process chamber to project high pressured first etching gas into the process chamber 310 in order to rapidly etch a wafer with large area, and a second plasma unit 342 connected with the process chamber 310 to project low pressured second etching gas into the process chamber in order to remove stress of the wafer and to make wanted roughness of the wafer.

The wafer transferring device 400 transfers the wafer aligned in the aligner 200 to the dry etching device 300. The wafer transferring device 400 includes a transfer chamber 410, a second gate valve 420, a transferring arm 430 and an end effector 440. The transfer chamber 410 is connected with the process chamber, the transfer chamber 410 is also connected to a dry pump, and the transfer chamber 410 includes a second gate valve to vacuate the chamber after transferring the wafer into chamber. The transferring arm 430 is installed in the transfer chamber 410 to transfer the wafer. The end effector 440 capable of absorbing the wafer is connected to an end portion of the transferring arm 430. The end effector 440 is formed such that the end effector 440 is able to attach the wafer for transferring the wafer having a thin thickness without damage. The end effector 440 can transfer the wafer in various methods.

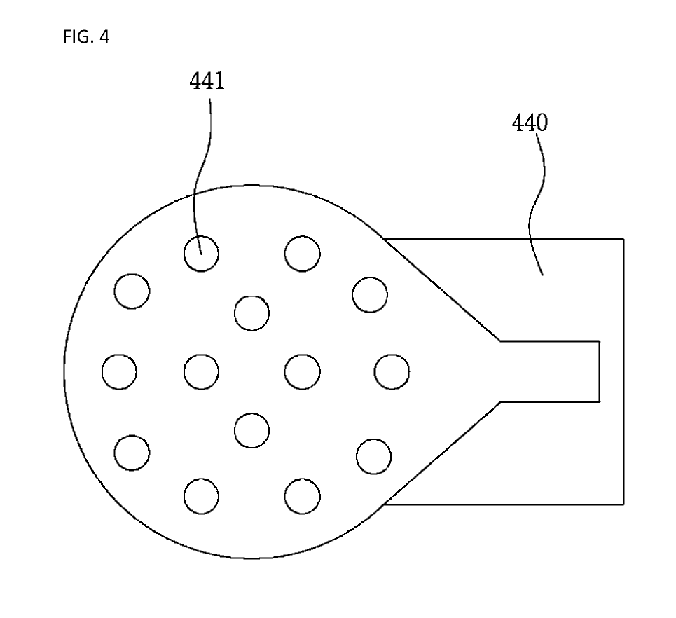

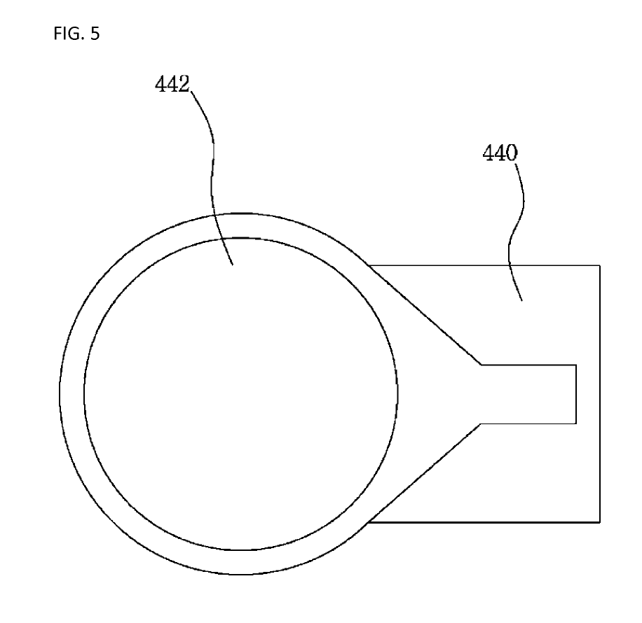

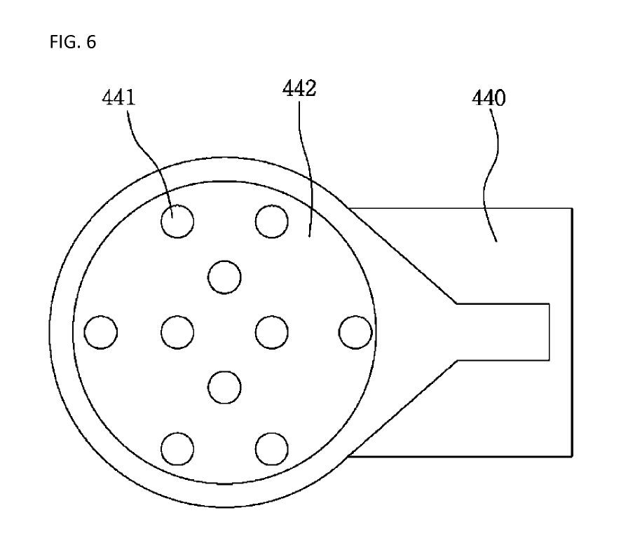

FIG. 4 is a figure showing an adhesion type end effector of a wafer etching system according to an embodiment of the present invention. FIG. 5 is a figure showing an electrostatic end effector of a wafer etching system according to an embodiment of the present invention. FIG. 6 is a figure showing a hybrid end effector of the adhesion type end effector and the electrostatic end effector, the hybrid end effector of a wafer etching system according to an embodiment of the present invention.

Referring to FIG. 4, an adhesion type end effector with an adhesive spreaded in a regular pattern for attaching a wafer may be used as the end effector 440. The wafer attached to the adhesion type end effector through the adhesive to be transferred is disposed on the chuck in the process chamber. The adhesive of the adhesion type end effector may be formed in a pattern with protrusion and attached to the end effector horizontally. The adhesion of the adhesion type end effector may be formed by urethane rubber, silicone rubber, etc.

For another example, referring to FIG. 5, an electrostatic end effector, to which an electrostatic part 442 generating static electricity is connected, may be used as the end effector 440. The electrostatic end effector applies +, − poles to the electrostatic part to generate static electricity, and the wafer is attached through the static electricity to be transferred.

For still another example, referring to FIG. 6, a hybrid type end effector of the adhesion type end effector and the electrostatic end effector may be used as the end effector. The adhesive is attached to the electrostatic end effector generating static electricity in a regular pattern for enforcing attachment, so that more stable transferring becomes possible.

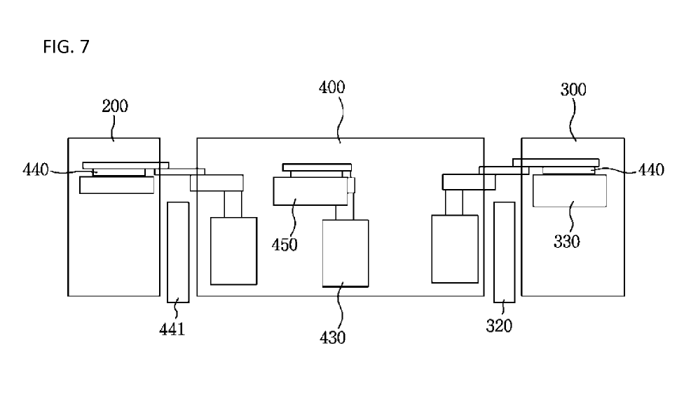

On the other hand, as shown in FIG. 7, the wafer transferring device 400 may further include a wafer-drop prevention device 450. The wafer-drop prevention device 450 is installed in the transfer chamber, and prevents the wafer from dropping from the chuck, while making the transfer chamber vacuum. The wafer-drop prevention device 450 may have a cylindrical shape, and prevents a wafer dropping which is induced by pressure change after the transferring arm 430 transfers the end effector 440 to be disposed over the wafer-drop prevention device 450 and the chamber is made vacuous.

The tape mouter 500 performs taping to the wafer that is etched by the dry etching device.

Hereinafter, a process of the wafer etching system according to an embodiment of the present invention will be explained as follows.

The process of the wafer etching system includes firstly grinding a wafer by a wafer grinding device, transferring the wafer to an aligner, attaching the wafer by an end effector of a wafer transfer device, transferring the wafer attached to the end effector into a transfer chamber, closing a second gate valve to vacuate the transfer chamber, opening a first gate valve when a vacuum state of the transfer chamber becomes equal to a vacuum state of a process chamber to transfer the wafer in the transfer chamber onto a chuck in the process chamber, separating the wafer from the end effector by applying static electricity to the chuck and forming vacuum by a vacuum forming part, closing the first gate valve to highly vacuate the process chamber to etch the wafer, attaching the wafer that is etched to the end effector when etching is completed, opening the first gate value and the second gate valve to transfer the wafer to the aligner, and transferring the wafer to a tape mounter to performs taping.

On the other hand, the process of etching a wafer with frame attached thereto, includes firstly grinding a wafer by a wafer grinding device, transferring the wafer to an aligner, transferring the wafer to a tape mounter to perform taping, transferring the wafer with a tape to the aligner and attaching the wafer by an end effector of a wafer transfer device, transferring the wafer attached to the end effector into a transfer chamber, closing a second gate valve to vacuate the transfer chamber, opening a first gate valve when a vacuum state of the transfer chamber becomes equal to a vacuum state of a process chamber to transfer the wafer in the transfer chamber onto a chuck in the process chamber, separating the wafer from the end effector by applying static electricity to the chuck and forming vacuum by a vacuum forming part, lowering a masking ring for protect a taping portion on the wafer, closing the first gate valve to highly vacuate the process chamber to etch the wafer, raising the masking ring when the etching is finished, attaching the wafer that is etched to the end effector, and opening the first gate value and the second gate valve to transfer the wafer to the aligner.

The wafer etching, as described above, may be divided into a case in which only a wafer is disposed in the process chamber to be etched, and a case in which a wafer with a UV or other adhesive tape attached thereto is disposed in the process chamber to be etched. The process with attaching the frame is one method for preventing a warpage of a wafer, which is a problem of forming thin wafer, and for preventing a sagging while transferring.

The transferring of a wafer is performed in vacuum, and the adhesion type end effector or the electrostatic end effector is used as the end effector for transferring when only a thin wafer is transferred. When a wafer with a frame attached thereto is transferred, a robot for only frame transferring is used.

When loading a wafer onto the electrostatic chuck in the process chamber by using the adhesive end effector, the cooling gas hole of the electro static chuck surface makes vacuum, and in this case, the vacuum in the chamber is higher than the vacuum between the wafer and the cooling gas hole. On the other hand, when dechucking the wafer from the electrostatic chuck in the process chamber by using the adhesive end effector, gas is provided to the cooling gas hole to minimize sticky phenomenon of the electro static chuck surface, which is remaining when the electro static chuck is off.

When loading a wafer onto the electrostatic chuck in the process chamber by using the electrostatic end effector, the cooling gas hole of the electro static chuck surface makes vacuum, the electrostatic chuck is turned off, and in this case, the vacuum in the chamber is higher than the vacuum between the wafer and the cooling gas hole. On the other hand, when dechucking the wafer from the electrostatic chuck in the process chamber by using the electrostatic end effector, gas is provided to the cooling gas hole to minimize sticky phenomenon of the electro static chuck surface, which is remaining when the electro static chuck is off. The electrostatic end effector is driven and used in a lower voltage than a voltage of the chuck in the process chamber.

In case of the wafer with the frame, the frame and the tape portion are protected by using the masking ring of ceramic in order to prevent arc and tape burning during the etching process. In case of the wafer with the frame, the robot arm supports the frame to move the wafer.

According to the wafer etching system and the wafer etching process, the wafer is transferred to the transfer chamber by an in-line automation system after wafer grinding, transferred to the process chamber to be dry etched and then transferred again to the transfer chamber to be conveyed to the wafer mounter, so that productivity is enhanced.

Further, the surface remaining stress generated in the grinding process is removed during dry etching by using plasma to enhance surface strength and to prevent wafer crack in advance.

According the adhesive chuck used for wafer transferring, all surface of the wafer is attached to the adhesive chuck to be transferred so that the wafer warpage and the wafer sagging, that are generated when the wafer is transferred by a conventional method in which a lower surface of the wafer is lifted and transferred, are prevented.

Further, according to the electrostatic chuck, the mischucking due to surface pollution when transferring to chamber is minimized, and wafer circuit damage is minimized since lower voltage is applied thereto.

Further, the wafer etching process etching the wafer with the frame prevents the wafer warpage and sagging of the wafer while transferring, and reduces wafer distortion while etching through a tension of the tape attached between the frame and the wafer so that reduction of electrostatic force induced by the wafer distortion when loading the wafer onto the chuck is detected in advance.

In the specifications, the present invention is explained referring to the preferred embodiments. However, it will be apparent to those skilled in the art that various modifications and variation can be made in the present invention without departing from the spirit or scope of the invention described in the claims to be described below.

What is claimed is:

1. A wafer etching system capable of reducing a thickness of a wafer while removing stress remaining in the wafer, which is generated by mechanical etching, the wafer etching system comprising:
a wafer grinding device etching the wafer mechanically;
an aligner aligning the wafer that is etched by the wafer grinding unit;
a dry etching device etching the wafer again, which is aligned by the aligner;
a wafer transfer device transferring the wafer between the aligner and the dry etching device;
a tape mounter performing taping process to the wafer that is etched by the dry etching device.

2. The wafer etching system of claim 1, wherein the dry etching device comprises:
a process chamber capable of rapidly maintaining vacuum state;
a first gate valve configured to open and to close the process chamber to be connected to the wafer transfer device;
a chuck installed in the process chamber to support the wafer transferred by the wafer transfer unit;
a plasma unit connected to the process chamber to etch the wafer of large area rapidly, which is supported by the chuck.

3. The wafer etching system of claim 2, wherein the chuck comprises:
an electrostatic part configured to apply static electricity;
a cooling gas providing part providing cooling gas through a cooling gas hole penetrating the electro static part;
a vacuum forming part configured to form a vacuum through the cooling gas hole;
an on/off valve configured to be turned on/off to connect the cooling gas providing part and the vacuum forming part to the cooling gas hole;
an adjust valve adjusting a degree of vacuum of the vacuum forming part and adjusting an amount of cooling gas of the cooling gas providing part.

4. The wafer etching system of claim 3, wherein the chuck comprises:
a masking ring for protecting UV tape attached to the wafer when the wafer is dry etched after taping is completed by the tape mounter; and
an elevating device raising and lowering the masking ring.

5. The wafer etching system of claim 2, wherein the plasma unit comprises:
a first plasma unit connected with the process chamber to project high pressured first etching gas into the process chamber in order to rapidly etch a wafer with large area;
a second plasma unit connected with the process chamber to project low pressured second etching gas into the process chamber in order to remove stress of the wafer and to make wanted roughness of the wafer.

6. The wafer etching system of claim 1, wherein the wafer transfer device comprises:
a transfer chamber rapidly maintaining vacuum state;
a second gate valve opening or closing the transfer chamber;
a transferring arm installed in the transfer chamber to transfer the wafer;
an end effector connected to an end portion of the transferring arm, the end effector having adhesive spreaded thereon in a regular pattern.

7. The wafer etching system of claim 1, wherein the wafer transfer device comprises:
a transfer chamber rapidly maintaining vacuum state;
a second gate valve opening or closing the transfer chamber;
a transferring arm installed in the transfer chamber to transfer the wafer;
an end effector connected to an end portion of the transferring arm, the end effector being capable of applying static electricity.

8. The wafer etching system of claim 1, wherein the wafer transfer device comprises:
a transfer chamber rapidly maintaining vacuum state;
a second gate valve opening or closing the transfer chamber;
a transferring arm installed in the transfer chamber to transfer the wafer;
an end effector connected to an end portion of the transferring arm, the end effector capable of attaching the wafer thereto, and wherein the end effector capable of applying static electricity has adhesive spreaded thereon in a regular pattern.

9. The wafer etching system of claim 6, wherein the wafer transfer device further comprises:
a wafer-drop prevention device installed in the transfer chamber for preventing the wafer from being dropped from the end effector when forming vacuum.

10. A wafer etching process comprising:
firstly grinding a wafer by a wafer grinding device;
transferring the wafer to an aligner;
attaching the wafer by an end effector of a wafer transfer device;
transferring the wafer attached to the end effector into a transfer chamber;
closing a second gate valve to vacuate the transfer chamber;
opening a first gate valve when a vacuum state of the transfer chamber becomes equal to a vacuum state of a process chamber to transfer the wafer in the transfer chamber onto a chuck in the process chamber;
separating the wafer from the end effector by applying static electricity to the chuck and forming vacuum by a vacuum forming part;
closing the first gate valve to highly vacuate the process chamber to etch the wafer;
attaching the wafer that is etched to the end effector when etching is completed;
opening the first gate value and the second gate valve to transfer the wafer to the aligner;
transferring the wafer to a tape mounter to performs taping.

11. A wafer etching process comprising:
firstly grinding a wafer by a wafer grinding device;
transferring the wafer to an aligner;
transferring the wafer to a tape mounter to perform taping;
transferring the wafer with a tape to the aligner and attaching the wafer by an end effector of a wafer transfer device;
transferring the wafer attached to the end effector into a transfer chamber;
closing a second gate valve to vacuate the transfer chamber;
opening a first gate valve when a vacuum state of the transfer chamber becomes equal to a vacuum state of a process chamber to transfer the wafer in the transfer chamber onto a chuck in the process chamber;
separating the wafer from the end effector by applying static electricity to the chuck and forming vacuum by a vacuum forming part;
lowering a masking ring for protect a taping portion on the wafer;
closing the first gate valve to highly vacuate the process chamber to etch the wafer;
raising the masking ring when the etching is finished;
attaching the wafer that is etched to the end effector;
opening the first gate value and the second gate valve to transfer the wafer to the aligner.
